(19) United States
(12) Patent Application Publication
(10) Pub. No.: US 2024/0388287 A1
(43) Pub. Date: Nov. 21, 2024

(54) VOLTAGE CONVERTER, AND DRIVER AND DRIVING METHOD OF POWER SWITCHING DEVICE

(71) Applicant: Chengdu Monolithic Power Systems Co., Ltd., Chengdu (CN)

(72) Inventor: Naixing Kuang, Hangzhou (CN)

(21) Appl. No.: 18/662,063

(22) Filed: May 13, 2024

(30) Foreign Application Priority Data
May 17, 2023 (CN) 202310561973.1

(51) Int. Cl. H03K 17/30; H03K 17/284; H03K 17/687

(52) U.S. Cl. CPC H03K 17/302; H03K 17/284; H03K 17/6871

(57) ABSTRACT

The present application discloses a voltage converter, and a driver and a driving method for a power switching device. The driver for the power switching device may include an input terminal for receiving a switching control signal and an output terminal for providing a driving voltage. When the switching control signal is at a first state, the driver may control the power switching device to be turned on according to a current flowing through the control terminal of the power switching device, and when the switching control signal is at a second state, the driver may control the power switching device to be turned off. The present application may beneficially reduce a voltage between two power terminals of the power switching device when the power switching device is turned on.

### CROSS-REFERENCE TO RELATED APPLICATIONS

This application claims priority to, and the benefit of, Chinese application No. 202310561973.1 filed on May 17, 2023, which is incorporated herein by reference in its entirety.

### TECHNICAL FIELD OF THE PRESENT INVENTION

The present invention relates to electronic circuits, in particular but not exclusively to drivers and associated driving methods for power switching devices and voltage converters including one or more of the drivers.

### BACKGROUND OF THE PRESENT INVENTION

In the prior art, a driving circuit is needed to control the on-off of a controllable power switching device. As shown in FIG. 1, a driver 10 receives a switching control signal PWM and generates a driving voltage Vg according to the switching control signal PWM to drive a power switching device S1. For example, when the switching control signal PWM changes to logic high, the driving voltage Vg controls the power switching device S1 to be turned on, and when the switching control signal PWM changes to logic low, the driving voltage Vg controls the power switching device S1 to be turned off. However, to improve the efficiency, it is necessary to control the power switching device S1 to work substantially under soft switching mode.

### SUMMARY OF THE PRESENT INVENTION

An embodiment of the present invention proposes a driver for a power switching device. The driver may include an input terminal and an output terminal. The input terminal may be configured to receive a switching control signal. The output terminal may be coupled to a control terminal of the power switching device and may be configured to provide a driving voltage to control turn-on and turn-off switching of the power switching device. When the switching control signal is at a first state, the driver may be configured to control the power switching device to be turned on according to a current flowing through the control terminal of the power switching device, and when the switching control signal is at a second state, the driver may be configured to control the power switching device to be turned off.

An embodiment of the present invention further proposes a driver for a power switching device. The driver may include an input pin, a first output pin, a second output pin, a power supply pin, a reference ground pin, a control circuit, and a driving circuit. The input pin may be configured to receive a switching control signal. The first output pin may be coupled to a control terminal of the power switching device through a first resistor. The second output pin may be coupled to the control terminal of the power switching device through a second resistor. The power supply pin may be configured to receive a power supply voltage. The control circuit may be configured to generate a driving control signal according to the switching control signal and a current flowing through the control terminal of the power switching device. The driving circuit may be coupled between the power supply pin and the reference ground pin and may be configured to control turn-on and turn-off switching of the power switching device through the first output pin and the second output pin under the control of the driving control signal.

An embodiment of the present invention further proposes a driver for a first power switching device. The driver may include a first input pin, a first output pin, a first power supply pin, a first reference ground pin, a second power supply pin, a second reference ground pin, a first control circuit, and a first driving circuit. The first input pin may be configured to receive a first switching control signal. The first output pin may be coupled to a control terminal of the first power switching device, and configured to provide a first driving voltage to the control terminal of the first power switching device. The first power supply pin may be configured to receive a first power supply voltage. The second power supply pin may be configured to receive a second power supply voltage. The first control circuit may be coupled to the first reference ground pin and the first power supply pin to receive the first power supply voltage and may be configured to generate a first driving control signal according to the first switching control signal and a current flowing through the control terminal of the first power switching device, where the first driving control signal and the first switching control signal are electrically isolated by an isolating capacitor. The first driving circuit may be coupled between the second power supply pin and the second reference ground pin and may be configured to generate the first driving voltage under the control of the first driving control signal. The driver may be further configured to drive a second power switching device, and the driver may further include: a second input pin configured to receive a second switching control signal; and a second output pin coupled to a control terminal of the second power switching device and configured to provide a second driving voltage to the control terminal of the second power switching device.

An embodiment of the present invention further proposes a voltage converter including a power switching device and any one of the above-mentioned drivers.

An embodiment of the present invention further proposes a driving method of a power switching device. The method may include the following steps: receiving a switching control signal; sensing a current flowing through a control terminal of the power switching device to generate a current sensing signal; and providing, according to the switching control signal and the current sensing signal, a driving voltage to the control terminal of the power switching device to control turn-on and turn-off switching of the power switching device; where when the switching control signal is at a first state, controlling the power switch device to be turned on according to a comparison result of the current sensing signal and a current threshold; and when the switching control signal is at a second state, controlling the power switching device to be turned off.

According to the embodiment of the present invention, a delay time between a moment when the switching control signal changes to the first state and a moment when the driving voltage starts to change to turn on the power switching device may be adjusted, the voltage between two power terminals of the power switching device when turning on the power switching device may be reduced, and thus the efficiency may be improved.

### BRIEF DESCRIPTION OF DRAWINGS

The following drawings are provided to better understand the following description of the embodiments of the present invention.

FIG. 1 is a schematic circuit diagram of an existing driver 10.

FIG. 2 is a schematic circuit diagram of a driver 20 adapted to drive a power switching device S1, according to an embodiment of the present invention.

FIG. 3 shows a waveform graph illustrating waveforms of several signals in the driver 20 adapted to drive the power switching device S1 shown in FIG. 2, according to an embodiment of the present invention.

FIG. 4 is a schematic circuit diagram of a driver 30 adapted to drive the power switching device S1, according to an embodiment of the present invention.

FIG. 5A is a schematic circuit diagram of a zero-voltage turn-on control circuit 22A, according to an embodiment of the present invention.

FIG. 5B is a schematic circuit diagram of a zero-voltage turn-on control circuit 22B, according to another embodiment of the present invention.

FIG. 6 is a schematic circuit diagram of a logic circuit 23A, according to an embodiment of the present invention.

FIG. 7 is a schematic circuit diagram of a logic circuit 23B, according to another embodiment of the present invention.

FIG. 8 is a schematic circuit diagram of a signal processing circuit 24A, according to an embodiment of the present invention.

FIG. 9A shows a waveform graph illustrating waveforms of several signals in the driver 30 adapted to drive the power switching device S1 shown in FIG. 4, according to an embodiment of the present invention.

FIG. 9B shows a waveform graph illustrating waveforms of several signals in the driver 30 adapted to drive the power switching device S1 shown in FIG. 4, according to another embodiment of the present invention.

FIG. 10 is a schematic circuit diagram of a driver 30B adapted to drive the power switching device S1, according to an embodiment of the present invention.

FIG. 11 is a schematic circuit diagram of a signal processing circuit 29A, according to an embodiment of the present invention.

FIG. 12 is a schematic circuit diagram of a logic circuit 33A, according to an embodiment of the present invention.

FIG. 13 is a schematic circuit diagram of a switching converter 800, according to an embodiment of the present invention.

FIG. 14 is a waveform graph illustrating waveforms of several signals in the switching converter 800 shown in FIG. 13, according to an embodiment of the present invention.

FIG. 15 is a schematic circuit diagram of a switching converter 900, according to an embodiment of the present invention.

FIG. 16 is a schematic circuit diagram of a driver 140 for driving a power switching device 130, according to an embodiment of the present invention.

FIG. 17 is a flowchart of a driving method 1100 of a power switching device, according to an embodiment of the present invention.

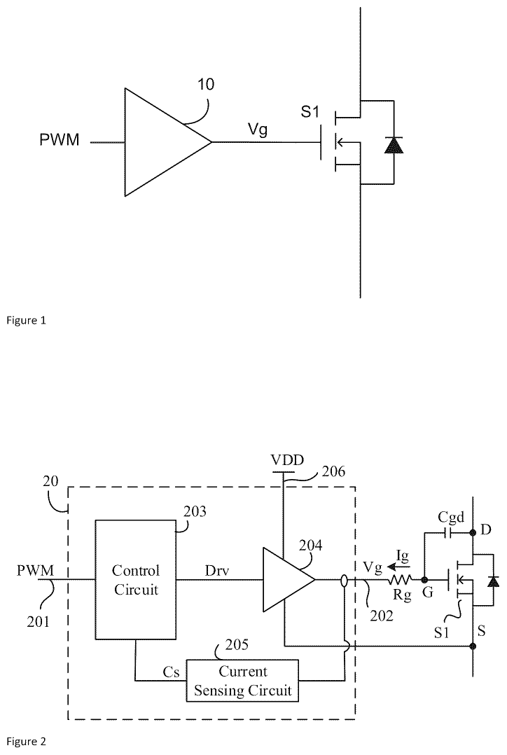

In the drawings, the same or corresponding reference numerals are used to indicate the same or corresponding elements.

### DETAILED DESCRIPTION OF THE PRESENT INVENTION

Hereinafter, specific embodiments of the present invention will be described in detail, and it should be noted that the embodiments described herein are only for illustration and are not intended to limit the present invention. In the following description, numerous specific details are set forth in order to provide a thorough understanding of the present invention. However, it will be apparent to one having ordinary skills in the art that these specific details are not necessary to practice the present invention. In other instances, well-known circuits, materials or methods are not described in detail in order to avoid obscuring the present invention.

Throughout this specification, references to “one embodiment”, “an embodiment”, “one example” or “an example” mean that a particular feature, structure or characteristic described in connection with this embodiment or example is included in at least one embodiment of the present invention. Therefore, the phrases “in one embodiment”, “in an embodiment”, “one example” or “an example” appearing in various places throughout the specification do not necessarily all refer to the same embodiment or example. Furthermore, specific features, structures or characteristics may be combined in any suitable combination and/or sub-combination in one or more embodiments or examples. Furthermore, it should be understood by those skilled in the art that the drawings provided herein are for illustration purposes and are not necessarily drawn to scale. When an element is said to be “coupled” or “connected” to another element, it may be directly coupled or connected to another element, or an intervening element may be present therebetween. Conversely, when an element is said to be “directly coupled” or “directly connected” to another element, there are no intervening elements. Like reference numerals indicate like elements. The term “and/or” as used herein includes any and all combinations of one or more related listed items.

FIG. 2 is a schematic circuit diagram of a driver 20 adapted to drive a power switching device S1, according to an embodiment of the present invention. As shown in FIG. 2, the power switching device S1 may include a control terminal G, a power terminal D, and a power terminal S. There is a parasitic capacitance Cgd between the control terminal G and the power terminal D of the power switching device S1. The power switching device S1 may include, for example, a Metal Oxide Semiconductor Field Effect Transistor (MOSFET), or a Junction Field Effect Transistor (JFET), or an Insulated Gate Bipolar Transistor (IGBT), or the like.

In the embodiment shown in FIG. 2, the driver 20 may include an input terminal 201 for receiving a switching control signal PWM, an output terminal 202 for providing a driving voltage Vg, a power supply terminal 206 for receiving a power supply voltage VDD, a control circuit 203, and a driving circuit 204. The switching control signal PWM may include, for example, a pulse width modulation signal. The output terminal 202 of the driver 20 may be coupled to the control terminal G of the power switching device S1 and may provide the driving voltage Vg to control the turn-on and turn-off switching of the power switching device S1. The control circuit 203 may generate a driving control signal Drv according to the switching control signal PWM and a current Ig flowing through the control terminal G of the power switching device S1. The driving circuit 204 may be coupled between the power supply terminal 206 and the power terminal S of the power switching device S1 and may be configured to generate the driving voltage Vg at least partially under the control of the driving control signal Drv. In one implementation, a maximum voltage value of the driving voltage Vg may be related to the power supply voltage VDD, for example, the maximum voltage value may be equal to the power supply voltage VDD, or equal to the power supply voltage VDD minus a voltage threshold Vth. When the switching control signal PWM is at a first state (e.g., logic high), the driver 20 may control the power switching device S1 to be turned on according to the current Ig flowing through the control terminal G of the power switching device S1, and when the switching control signal PWM is at a second state (e.g., logic low), the driver 20 may control the power switching device S1 to be turned off. In one embodiment, the driver 20 may adaptively adjust, according to the current Ig flowing through the control terminal G of the power switching device S1, a delay time Td between a moment when the switching control signal PWM changes to the first state and a moment when the driving voltage Vg starts to change to turn on the power switching device S1. As a result, a voltage Vds between the two power terminals D and S of the power switching device S1 when the power switching device S1 is turned on may be reduced, and the power switching device S1 may be turned on with the voltage Vds at a lower voltage, such as at zero-voltage or near zero-voltage.

In the embodiment shown in FIG. 2, the driver 20 may further include a current sensing circuit 205. The current sensing circuit 205 may provide a current sensing signal Cs by sensing the current Ig flowing through the control terminal G of the power switching device S1. In one embodiment, the control circuit 203 may generate the driving control signal Drv according to the switching control signal PWM and the current sensing signal Cs, and when the switching control signal PWM is at the first state, the control circuit 203 may control the power switching device S1 to be turned on according to the current sensing signal Cs.

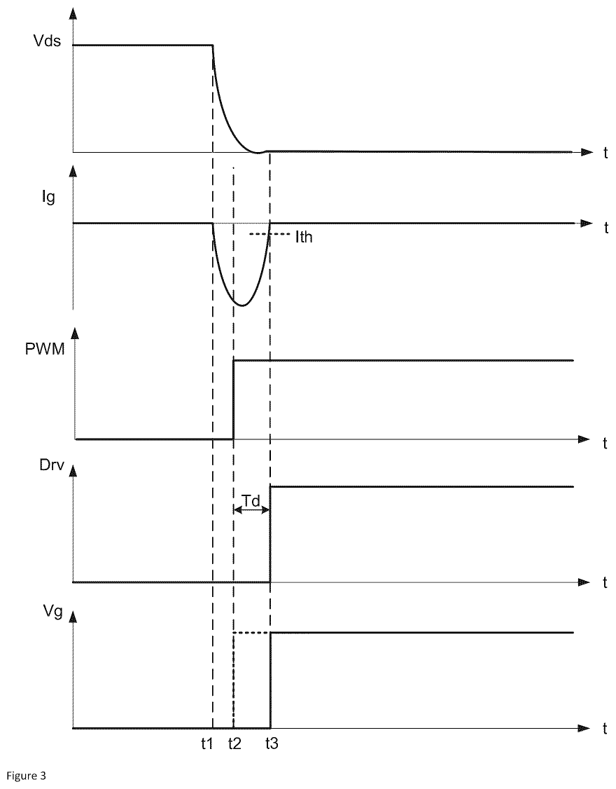

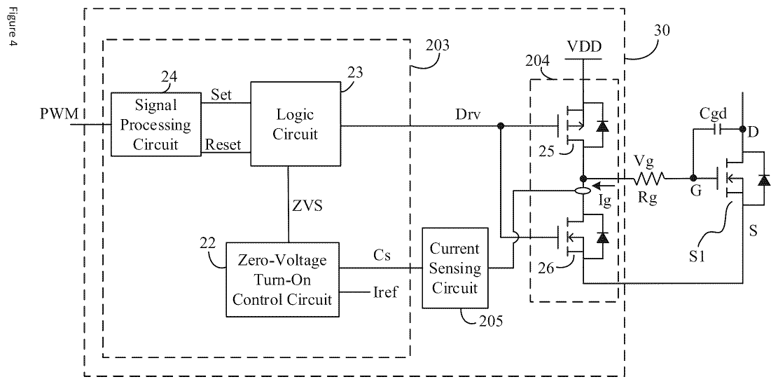

FIG. 3 shows a waveform graph illustrating waveforms of several signals in the driver 20 adapted to drive the power switching device S1 as shown in FIG. 2, according to an embodiment of the present invention. From top to bottom, waveforms of the voltage Vds between the two power terminals D and S of the power switching device S1, the current Ig flowing through the control terminal G of the power switching device S1, the switching control signal PWM, the driving control signal Drv, and the driving voltage Vg are shown.

An embodiment of the present invention may determine whether to turn on the power switching device S1 with the assistance of the current Ig flowing through the control terminal G. In one embodiment, under the effect of the parasitic capacitance Cgd of the power switching device S1, when the driving voltage Vg controls the power switching device S1 to remain off, the current Ig flowing through the control terminal G is equal to a current flowing through the parasitic capacitance Cgd, and the current Ig reflects the voltage change at the power terminal D of the power switching device S1, so it may be used to assist in determining the condition of the voltage Vds between the two power terminals D and S of the power switching device S1.

In the embodiment shown in FIG. 3, the first state of the switching control signal PWM is logic high, and the second state of the switching control signal PWM is logic low, just to provide an example. Before time t1, both the switching control signal PWM and the driving control signal Drv are at logic low, the driving voltage Vg is equal to 0V, and the power switching device S1 remains off. At the time t1, under the effect of external circuits, the voltage at the power terminal D of the power switching device S1 decreases, the voltage Vds between the two power terminals D and S of the power switching device S1 begins to decrease, and the current Ig flows from the control terminal G to the power terminal D. The current Ig is as illustratively shown in FIG. 3.

At time t2, the switching control signal PWM becomes logic high, while the current Ig is still flowing from the control terminal G to the power terminal D. The driver 20 controls the driving control signal Drv to remain at logic low, the driving voltage Vg remains to be 0V, and the power switching device S1 remains off. Until time t3, the current Ig flowing from the control terminal G to the power terminal D decreases to a threshold Ith (for example, 0A or near 0A), indicating that the voltage Vds between the two power terminals D and S of the power switching device S1 is at minimum, and the driver 20 controls the driving control signal Drv to become logic high, and the driving voltage Vg starts to increase to control the power switching device S1 to be turned on, so that the power switching device S1 may be turned on with the voltage Vds at a substantially zero-voltage or a substantially lower-voltage compared to that at the time t1 or t2.

In contrast, existing drivers generally control the driving voltage Vg to start increasing at the time t2 when the switching control signal PWM changes to the first state, as shown by the dotted line. From the moment when the switching control signal PWM changes to the first state to the moment when the driving voltage Vg starts increasing to control the power switching device S1 to be turned on, there is no controllable delay time even if there is an inherent propagation delay (not shown in the figure) for existing drivers. In an embodiment of the present invention, the delay time Td from the moment when the switching control signal PWM changes to the first state to the moment when the driving voltage Vg starts to change to control the power switching device S1 to be turned on may be adaptively adjusted according to the current Ig flowing through the control terminal G of the power switching device S1, so that the voltage Vds between the two power terminals D and S of the power switching device S1 when the power switching device S1 is turned on may be reduced. The embodiments of the present invention can adaptively realize zero-voltage turn-on or lower-voltage turn-on of the power switching device S1 without additional pins, and without depending on the load condition of the circuit where the power switching device S1 is located (for example, whether a load current is in a light load range or a heavy load range), and the circuit is simple and easy to design.

FIG. 4 is a schematic circuit diagram of a driver 30 adapted to drive the power switching device S1 according to an embodiment of the present invention. In the embodiment shown in FIG. 4, the driving circuit 204 may include switches 25 to 26. The specific circuit of the driving circuit 204 is not limited to the embodiment shown in FIG. 4. As shown in FIG. 4, the switch 25 and the switch 26 are coupled in series between the power supply voltage VDD and the power terminal S of the power switching device S1. That is, a first terminal of the switch 25 is coupled to the power supply voltage VDD, a first terminal of the switch 26 is coupled to a second terminal of the switch 25, and a second terminal of the switch 26 is coupled to the power terminal S of the power switching device S1. A common terminal of the switch 25 and the switch 26 (that is, the second terminal of the switch 25 and the first terminal of the switch 26) may provide a driving voltage Vg and may be coupled to the control terminal G of the power switching device S1 through a driving resistor Rg. The driving resistor Rg may include an independent resistor or a parasitic resistor, for example. A control terminal of the switch 25 and a control terminal of the switch 26 may be commonly coupled to the control circuit 203 to receive the driving control signal Drv. The switches 25 to 26 may include, for example, a Metal Oxide Semiconductor Field Effect Transistor (MOSFET), a Bipolar Junction Transistor (BJT), or the like. In one embodiment, for example, the switches 25-26 may each include an N-type Metal Oxide Semiconductor Field Effect Transistor (NMOS) or a P-type Metal Oxide Semiconductor Field Effect Transistor (PMOS), or as shown in FIG. 4, one of the switches is NMOS and the other is PMOS. In one embodiment, the current sensing circuit 205 may sense the current Ig flowing through the control terminal G of the power switching device S1 by sensing a current flowing through the switch 25 or the switch 26. The current sensing circuit 205 may include, for example, a current mirror, a current sensor, or a sensing resistor.

In the embodiment shown in FIG. 4, the control circuit 203 may further include a zero-voltage turn-on control circuit 22. The zero-voltage turn-on control circuit 22 may provide a zero-voltage turn-on control signal ZVS according to a comparison result of the current sensing signal Cs and a current threshold Iref. In one embodiment, when the current sensing signal Cs is less than the current threshold Iref, indicating that the current Ig flowing from the driver 30 to the control terminal G decreases to the threshold Ith, and at this time, the voltage Vds between the two power terminals D and S of the power switching device S1 basically decreases to the minimum, and the zero-voltage turn-on control signal ZVS is active, for example, becomes logic high. In one embodiment, when the switching control signal PWM is at the first state, the driver 30 may control the power switching device S1 to be turned on according to the comparison result of the current sensing signal Cs and the current threshold Iref. In one embodiment, when the power switching device S1 is turned on, the zero-voltage turn-on control signal ZVS is reset, for example, becomes logic low. In one embodiment, during a masking period Tblk after the power switching device S1 is turned off, the current sensing signal Cs may be masked, and the zero-voltage turn-on control signal ZVS may remain at logic low.

In the embodiment shown in FIG. 4, the control circuit 203 may further include a logic circuit 23. The logic circuit 23 may generate the driving control signal Drv according to the switching control signal PWM and the zero-voltage turn-on control signal ZVS, control the power switching device S1 to be turned on according to the switching control signal PWM and the zero-voltage turn-on control signal ZVS, and control the power switching device S1 to be turned off according to the switching control signal PWM.

In the embodiment shown in FIG. 4, the control circuit 203 may further include a signal processing circuit 24. The signal processing circuit 24 may provide a turn-on control signal Set and a turn-off control signal Reset according to the switching control signal PWM. When the switching control signal PWM is at the first state, the turn-on control signal Set is active, for example, at logic high, and is used, together with the zero-voltage turn-on control signal ZVS, to control the power switching device S1 to be turned on. When the switching control signal PWM is at the second state, the turn-off control signal Reset is active, for example, at logic high, and is used to control the power switching device S1 to be turned off. The logic circuit 23 may be further coupled to the signal processing circuit 24 to receive the turn-on control signal Set and the turn-off control signal Reset. The logic circuit 23 may control the power switching device S1 to be turned on according to the turn-on control signal Set and the zero-voltage turn-on control signal ZVS and control the power switching device S1 to be turned off according to the turn-off control signal Reset. For example, when the turn-on control signal Set and the zero-voltage turn-on control signal ZVS are both active (e.g., both at logic high), the driving control signal Drv becomes logic high, and the power switching device S1 is controlled to be turned on by the driving circuit 204. When the turn-off control signal Reset is active (e.g., at logic high), the driving control signal Drv changes to logic low, and the power switching device S1 is controlled to be turned off by the driving circuit 204.

FIG. 5A is a schematic circuit diagram of a zero-voltage turn-on control circuit 22A according to an embodiment of the present invention. In the embodiment shown in FIG. 5A, the zero-voltage turn-on control circuit 22A may include a masking circuit 221, a comparison circuit 222, and a logic circuit 223. The masking circuit 221 may provide a current sensing signal Cs1 according to the current sensing signal Cs and the driving control signal Drv. In one embodiment, during the masking period Tblk after the driving control signal Drv controls the power switching device S1 to be turned off, the masking circuit 221 may mask the current sensing signal Cs, and the current sensing signal Cs1 may remain unchanged. After the masking period Tblk, the current sensing signal Cs1 may be equal to the current sensing signal Cs. The comparison circuit 222 may include a first input terminal for receiving the current sensing signal Cs1, a second input terminal for receiving the current threshold Iref, and an output terminal. The comparison circuit 222 may provide a comparison signal Vc at its output terminal according to a comparison result of the current sensing signal Cs1 and the current threshold Iref. The comparison circuit 222 may include, for example, a comparator. In one embodiment, when the current sensing signal Cs1 is less than the current threshold Iref, the logic circuit 223 may set and output the zero-voltage turn-on control signal ZVS at logic high. When the power switching device S1 is turned on, the logic circuit 223 may reset and output the zero-voltage turn-on control signal ZVS at logic low. The logic circuit 223 may include, for example, an RS flip-flop, a set terminal S of which receives the comparison signal Vc, a reset terminal R of which receives a delayed driving control signal Drv through the delay circuit 224, and an output terminal Q of which outputs the zero-voltage turn-on control signal ZVS.

FIG. 5B is a schematic circuit diagram of a zero-voltage turn-on control circuit 22B according to an embodiment of the present invention. Compared with the circuit shown in FIG. 5A, in the embodiment shown in FIG. 5B, the driving voltage Vg is provided to the masking circuit 221 and the logic circuit 223 instead of the driving control signal Drv. The masking circuit 221 may provide the current sensing signal Cs1 according to the current sensing signal Cs and the driving voltage Vg. During the masking period Tblk after the driving voltage Vg controls the power switching device S1 to be turned off, the masking circuit 221 may mask the current sensing signal Cs, and the current sensing signal Cs1 may remain unchanged. After the masking period Tblk, the current sensing signal Cs1 may be equal to the current sensing signal Cs. In the embodiment shown in FIG. 5B, the logic circuit 223 may include, for example, an RS flip-flop, a set terminal S of which receives the comparison signal Vc, a reset terminal R of which receives the driving voltage Vg, and an output terminal Q of which outputs the zero-voltage turn-on control signal ZVS. When the driving voltage Vg controls the power switching device S1 to be turned on, the zero-voltage turn-on control signal ZVS may be reset to logic low. Those skilled in the art know that the specific circuit of the zero-voltage turn-on control circuit 22 is not limited to the embodiment shown in FIGS. 5A to 5B.

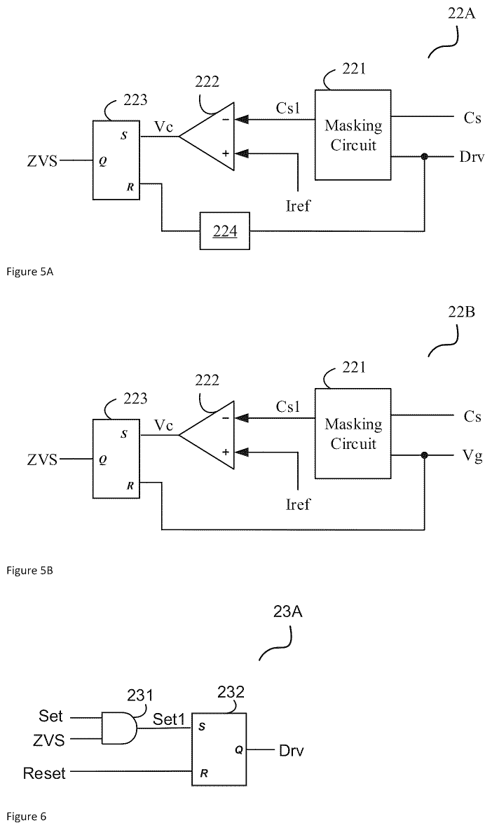

FIG. 6 is a schematic circuit diagram of a logic circuit 23A according to an embodiment of the present invention. In the embodiment shown in FIG. 6, the logic circuit 23A may include, for example, an AND gate 231 and an RS flip-flop 232. The AND gate 231 may receive the turn-on control signal Set and the zero-voltage turn-on control signal ZVS and generate a set signal Set1 according to the turn-on control signal Set and the zero-voltage turn-on control signal ZVS. A set terminal S of the RS flip-flop 232 may be coupled to the AND gate 231 to receive the set signal Set1. A reset terminal R of the RS flip-flop 232 may be coupled to the signal processing circuit 24 to receive the turn-off control signal Reset. An output Q of the RS flip-flop 232 may provide the driving control signal Drv.

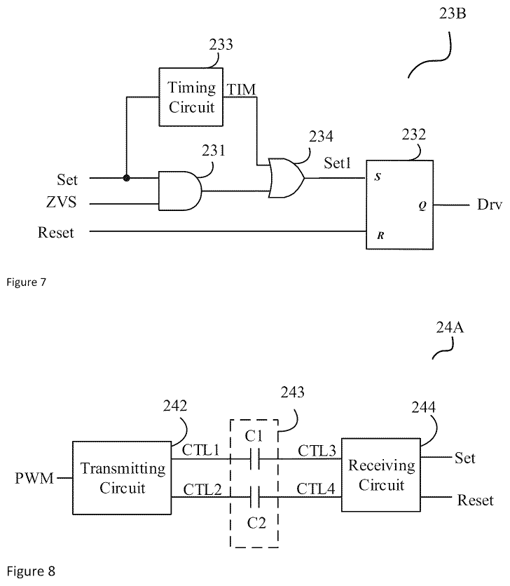

FIG. 7 is a schematic circuit diagram of a logic circuit 23B according to another embodiment of the present invention. In the embodiment shown in FIG. 7, the logic circuit 23B may further include a timing circuit 233 and an OR gate 234. In one embodiment, the timing circuit 233 may be used to control a maximum delay time Td between the moment when the switching control signal PWM changes to the first state and the moment when the driving voltage Vg starts to change to turn on the power switching device S1. In one embodiment, after the switching control signal PWM changes to the first state, the timing circuit 233 may start timing. If the current sensing signal Cs is greater than the current threshold Iref, then the zero-voltage turn-on control signal ZVS may remain at logic low and the power switching device S1 may remain off. When the timing duration reaches a preset duration Tpre, the timing circuit 233 may output a timing signal TIM which is at logic high, and the driving signal Drv may become logic high under the control of the timing signal TIM, so as to turn on the power switching device S1. The OR gate 234 may generate the set signal Set1 according to the timing signal TIM and an output signal of the AND gate 231, to control the power switching device S1 to be turned on. The specific circuit of the logic circuit 23 is not limited to the embodiment shown in FIGS. 6 to 7.

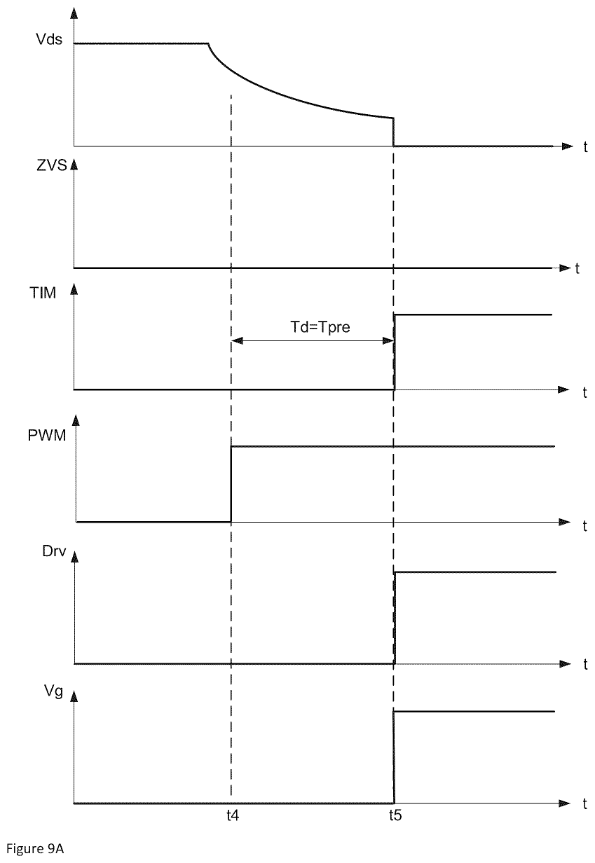

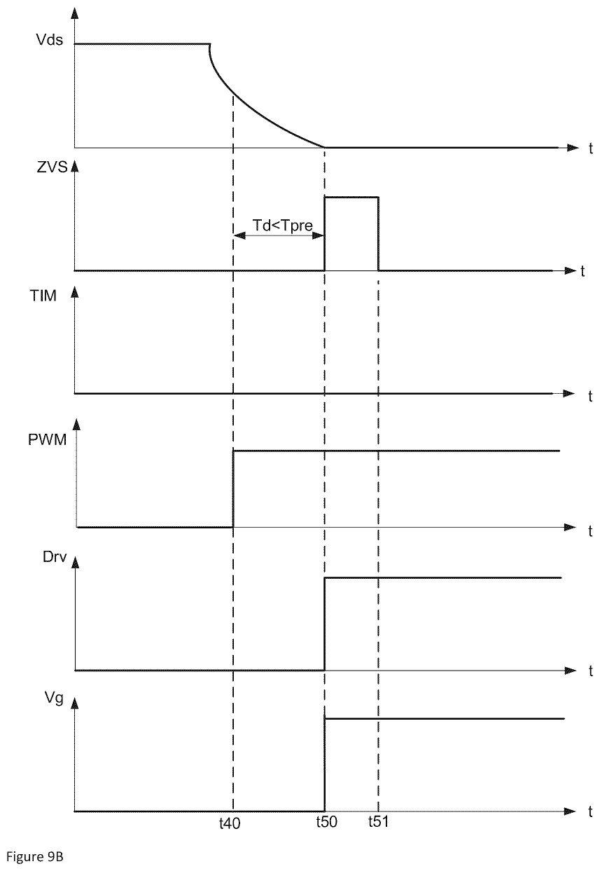

FIG. 8 is a schematic circuit diagram of a signal processing circuit 24A according to an embodiment of the present invention. The signal processing circuit 24A may include an isolating circuit 243 for electrically isolating the switching control signal PWM from the driving control signal Drv. In the embodiment shown in FIG. 8, the signal processing circuit 24A may electrically isolate the turn-on control signal Set from the switching control signal PWM through an isolating capacitor C1, and electrically isolate the turn-off control signal Reset from the switching control signal PWM through an isolating capacitor C2. In the embodiment shown in FIG. 8, the signal processing circuit 24 may further include a transmitting circuit 242 and a receiving circuit 244. The transmitting circuit 242 may receive the switching control signal PWM and generate control signals CTL1 to CTL2 according to the switching control signal PWM. The transmitting circuit 242 may include, for example, an oscillation circuit. The isolating circuit 243 may be coupled between the transmitting circuit 242 and the receiving circuit 244 to electrically isolate the transmitting circuit 242 and the receiving circuit 244. For example, the isolating capacitor C1 may receive the control signal CTL1 and provide a control signal CTL3 according to the control signal CTL1, and the isolating capacitor C2 may receive the control signal CTL2 and provide a control signal CTL4 according to the control signal CTL2. The receiving circuit 244 may receive the control signals CTL3 to CTL4 and provide the turn-on control signal Set and the turn-off control signal Reset according to the control signals CTL3 to CTL4. The receiving circuit 244 may include, for example, a receiving impedance, an amplifying circuit, and a signal processing circuit. The specific circuit of the signal processing circuit 24 is not limited to the embodiment shown in FIG. 8.

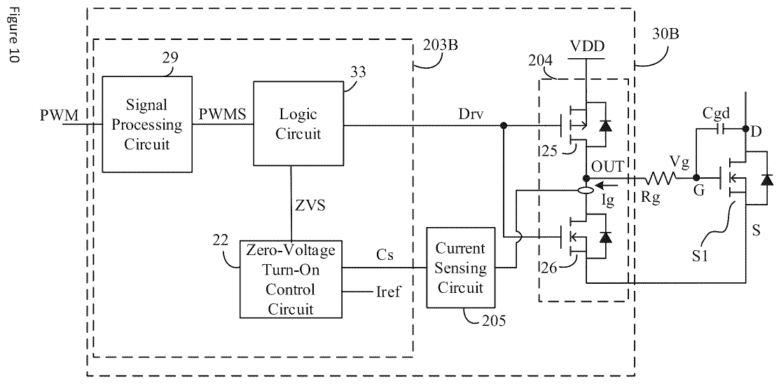

FIG. 9A shows a waveform graph illustrating waveforms of several signals in the driver 30 adapted to drive the power switching device S1 as shown in FIG. 4 according to an embodiment of the present invention. From top to bottom, waveforms of the voltage Vds between the two power terminals D and S of the power switching device S1, the zero-voltage turn-on control signal ZVS, the timing signal TIM, the switching control signal PWM, the driving control signal Drv, and the driving voltage Vg are shown. As shown in FIG. 9A, at time t4, the switching control signal PWM becomes logic high. During the time t4 to time t5, the zero-voltage turn-on control signal ZVS remains at logic low. Until the time t5, the delay time Td reaches the preset duration Tpre, the timing signal TIM becomes logic high, the driving control signal Drv becomes logic high accordingly, and the driving voltage Vg controls the power switching device S1 to be turned on.

FIG. 9B shows a waveform graph illustrating waveforms of several signals in the driver 30 adapted to drive the power switching device S1 as shown in FIG. 4 according to another embodiment of the present invention. From top to bottom, waveforms of the voltage Vds between the two power terminals D and S of the power switching device S1, the zero-voltage turn-on control signal ZVS, the timing signal TIM, the switching control signal PWM, the driving control signal Drv, and the driving voltage Vg are sequentially shown. As shown in FIG. 9B, at time t40, the switching control signal PWM becomes logic high. At time t50, the current Ig flowing from the driver 30 to the control terminal G of the power switching device S1 decreases to the threshold Ith, at which time the voltage Vds between the two power terminals D and S of the power switching device S1 decreases to about 0V, and the zero-voltage turn-on control signal ZVS changes to logic high, the driving signal Drv changes to logic high accordingly, and the driving voltage Vg controls the power switching device S1 to be turned on. In the embodiment shown in FIG. 9B, the delay time Td is less than the preset duration Tpre, and the timing signal TIM remains at logic low. After the power switching device S1 is turned on, for example, at time t51, the zero-voltage turn-on control signal ZVS is reset to logic low.

FIG. 10 is a schematic circuit diagram of a driver 30B adapted to drive a power switching device S1 according to an embodiment of the present invention. In the embodiment shown in FIG. 10, the driver 30B may include a control circuit 203B, the driving circuit 204, and the current sensing circuit 205. The control circuit 203B may include a signal processing circuit 29, a logic circuit 33, and the zero-voltage turn-on control circuit 22. The signal processing circuit 29 may provide an isolation control signal PWMS according to the switching control signal PWM, where the isolation control signal PWMS is electrically isolated from the switching control signal PWM, thereby electrically isolating the driving control signal Drv from the switching control signal PWM. The logic circuit 33 may be coupled to the signal processing circuit 29 and generate the driving control signal Drv according to the isolation control signal PWMS and the zero-voltage turn-on control signal ZVS.

FIG. 11 is a schematic circuit diagram of a signal processing circuit 29A according to an embodiment of the present invention. In the embodiment shown in FIG. 11, the signal processing circuit 29A may include a transmitting circuit 291, an isolating circuit 292, and a receiving circuit 293. The transmitting circuit 291 may receive the switching control signal PWM and generate a control signal CTL5. The isolating circuit 292 may receive the control signal CTL5 and generate a control signal CTL6 which is electrically isolated from the control signal CTL5. The receiving circuit 293 may receive the control signal CTL6 and generate the isolation control signal PWMS. The isolating circuit 292 may include, for example, a capacitor, a transformer, or an optical coupler.

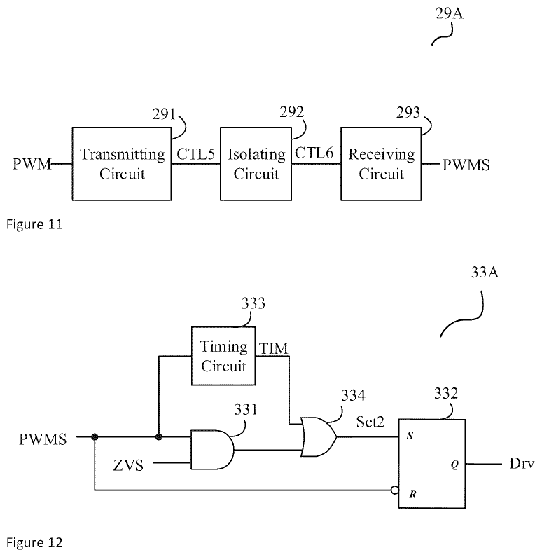

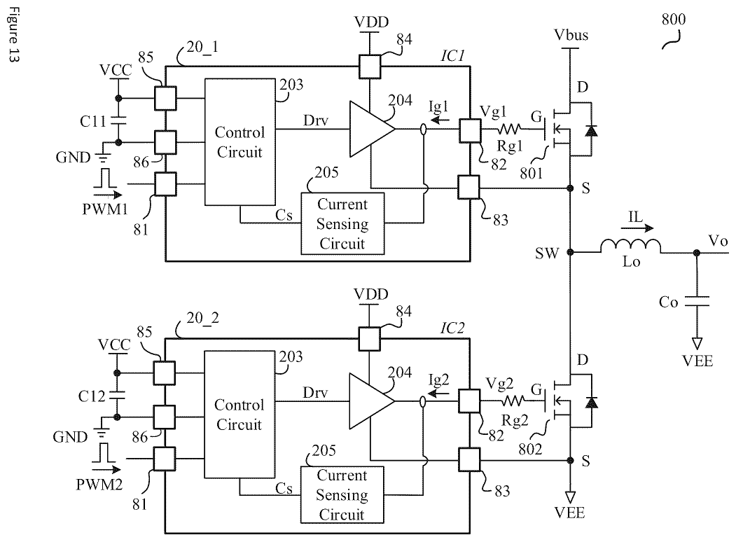

FIG. 12 is a schematic circuit diagram of a logic circuit 33A according to an embodiment of the present invention. In the embodiment shown in FIG. 12, the logic circuit 33A may include, for example, an AND gate 331, a timing circuit 333, an OR gate 334, and an RS flip-flop 332. The AND gate 331 may receive the isolation control signal PWMS and the zero-voltage turn-on control signal ZVS. The timing circuit 333 may perform timing according to the isolation control signal PWMS, and output a timing signal TIM to control the maximum delay time Td between the moment when the switching control signal PWM changes to the first state and the moment when the driving voltage Vg starts to change to turn on the power switching device S1. The OR gate 334 may generate a set signal Set2 according to the timing signal TIM and an output signal of the AND gate 331. A set terminal S of the RS flip-flop 332 may be coupled to the OR gate 334 to receive the set signal Set2, a reset terminal R of the RS flip-flop 232 may receive the isolation control signal PWMS, and an output terminal Q of the RS flip-flop 232 may provide the driving control signal Drv. The specific circuit of the logic circuit 33A is not limited to the embodiment shown in FIG. 12.

FIG. 13 is a schematic circuit diagram of a switching converter 800 according to an embodiment of the present invention. The embodiment shown in FIG. 13 is illustrated by taking a synchronous buck circuit as an example. The present invention may also be applied to any other topologies including power switching devices. In the embodiment shown in FIG. 13, the switching converter 800 may include power switching devices 801 to 802 and drivers 20_1 to 20_2. A power terminal D of the power switching device 801 may be coupled to an input voltage Vbus, and a power terminal D of the power switching device 802 may be coupled to a power terminal S of the power switching device 801 to form a switching node SW. The power terminal S of the power switching device 802 may be coupled to a reference ground VEE. One terminal of an output inductor Lo may be coupled to the switching node SW, and the other terminal of the output inductor Lo may provide an output voltage Vo. An output capacitor Co may be coupled between the output voltage Vo and the reference ground VEE. A control terminal G of the power switching device 801 may receive a driving voltage Vg1 provided by the driver 20_1 and the power switching device 801 may be turned on and off under the control of the driving voltage Vg1. A control terminal G of the power switching device 802 may receive a driving voltage Vg2 provided by the driver 20_2 and the power switching device 802 may be turned on and off under the control of the driving voltage Vg2.

In one embodiment, the driver 20_1 may be integrated on an integrated circuit IC1 and the driver 20_2 may be integrated on an integrated circuit IC2. Each driver (20_1, 20_2) may include an input pin 81, an output pin 82, a reference ground pin 83, a power supply pin 84, a power supply pin 85, a reference ground pin 86, the control circuit 203, the driving circuit 204, and the current sensing circuit 205.

The input pin 81 of the driver 20_1 may receive a switching control signal PWM1, the output pin 82 of the driver 20_1 may be coupled to the control terminal G of the power switching device 801 through a resistor Rg1 and provide the driving voltage Vg1 to control the turn-on and turn-off switching of the power switching device 801, the reference ground pin 83 of the driver 20_1 may be coupled to the power terminal S of the power switching device 801, and the power supply pin 84 of the driver 20_1 may receive the power supply voltage VDD. The power supply pin 85 of the driver 20_1 may receive a power supply voltage VCC, the reference ground pin 86 of the driver 20_1 may be coupled to a reference ground GND, and a capacitor C11 may be coupled between the power supply pin 85 and the reference ground pin 86. In one embodiment, the control circuit 203 of the driver 20_1 may be coupled to the power supply pin 85 and the reference ground pin 86, and the power supply voltage VCC may supply power to the control circuit 203 through the power supply pin 85. In one embodiment, the switching control signal PWM1 and the driving control signal Drv of the driver 20_1 may be electrically isolated from each other. The driver 20_1 may provide the driving voltage Vg1 according to a current Ig1 flowing through the control terminal G of the power switching device 801 and the switching control signal PWM1. The control circuit 203 of the driver 20_1 may generate the driving control signal Drv according to the switching control signal PWM1 and the current Ig1 flowing through the control terminal G of the power switching device 801. The driving circuit 204 of the driver 20_1 may be coupled between the power supply pin 84 and the reference ground pin 83 of the driver 20_1 and may generate the driving voltage Vg1 under the control of the driving control signal Drv.

The input pin 81 of the driver 20_2 may receive a switching control signal PWM2, the output pin 82 of the driver 20_2 may be coupled to the control terminal G of the power switching device 802 through a resistor Rg2 and may provide the driving voltage Vg2 to control the turn-on and turn-off switching of the power switching device 802, the reference ground pin 83 of the driver 20_2 may be coupled to the power terminal S of the power switching device 802, and the power supply pin 84 of the driver 20_2 may receive the power supply voltage VDD. The power supply pin 85 of the driver 20_2 may be coupled to the power supply voltage VCC, the reference ground pin 86 of the driver 20_2 may be coupled to the reference ground GND, and a capacitor C12 may be coupled between the power supply pin 85 and the reference ground pin 86. In one embodiment, the control circuit 203 of the driver 20_2 may be coupled to the power supply pin 85 and the reference ground pin 86, and the power supply voltage VCC may supply power to the control circuit 203 through the power supply pin 85. In one embodiment, the switching control signal PWM2 and the driving control signal Drv of the driver 20_2 may be electrically isolated from each other. The driver 20_2 may provide the driving voltage Vg2 according to a current Ig2 flowing through the control terminal G of the power switching device 802 and the switching control signal PWM2. The control circuit 203 of the driver 20_2 may generate the driving control signal Drv according to the switching control signal PWM2 and the current Ig2 flowing through the control terminal G of the power switching device 802. The driving circuit 204 of the driver 20_2 may be coupled between the power supply pin 84 and the reference ground pin 83 of the driver 20_2 and may generate the driving voltage Vg2 under the control of the driving control signal Drv.

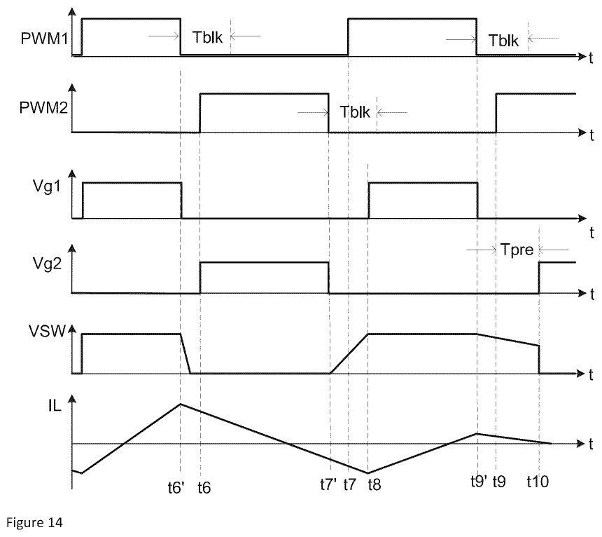

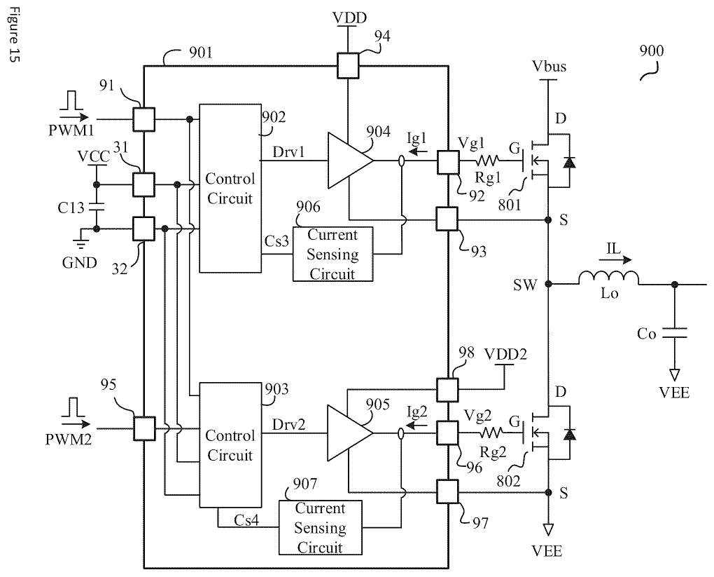

FIG. 14 is a waveform graph illustrating waveforms of several signals in the switching converter 800 shown in FIG. 13 according to an embodiment of the present invention. From top to bottom, waveforms of the switching control signal PWM1, the switching control signal PWM2, the driving voltage Vg1, the driving voltage Vg2, a voltage VSW at the switching node SW, and a current IL flowing through the output inductor Lo are sequentially shown.

In one embodiment, the driver 20_1 may mask its current sensing signal Cs during a masking period Tblk after the switching control signal PWM1 changes from logic high to logic low, and the control circuit 203 of the driver 20_1 may not determine whether a voltage between the two power terminals D and S of the power switching device 801 is over zero. Similarly, the driver 20_2 may mask its current sensing signal Cs during a masking period Tblk after the switching control signal PWM2 changes from logic high to logic low, and the control circuit 203 of the driver 20_2 may not determine whether a voltage between the two power terminals D and S of the power switching device 802 is over zero.

As shown in FIG. 14, at time t6′, the switching control signal PWM1 changes to logic low, the power switching device 801 is turned off under the control of the driving voltage Vg1, and the voltage VSW begins to decrease. At time t6, the switching control signal PWM2 changes to logic high, and at this time, the voltage VSW has stabilized at a minimum voltage (such as 0V), the current Ig2 flowing into the control terminal G of the power switching device 802 decreases to the threshold Ith, and the driver 20_2 controls the power switching device 802 to be turned on through the driving voltage Vg2. At time t7′, the switching control signal PWM2 changes to logic low, the power switching device 802 is turned off under the control of the driving voltage Vg2, and the voltage VSW begins to increase. At time t7, the switching control signal PWM1 changes to logic high, and at this time, the voltage VSW is during the process of increasing and the driving voltage Vg1 remains unchanged, and the driver 20_1 controls the power switching device 801 to remain off. Until time t8, the voltage VSW increases to and maintains at the input voltage Vbus, the current Ig1 flowing into the control terminal G of the power switching device 801 decreases to the threshold Ith, and the driver 20_1 controls the power switching device 801 to be turned on through the driving voltage Vg1. At time t9′, the switching control signal PWM1 changes to logic low, the power switching device 801 is turned off under the control of the driving voltage Vg1, and the voltage VSW begins to decrease. At time t9, the switching control signal PWM2 changes to logic high, while the voltage VSW is during the process of decreasing and the driving voltage Vg2 remains unchanged, and the driver 20_2 controls the power switching device 802 to remain off. Until time t10, the delay time Td reaches the preset duration Tpre, and the driver 20_2 controls the power switching device 802 to be turned on through the driving voltage Vg2.

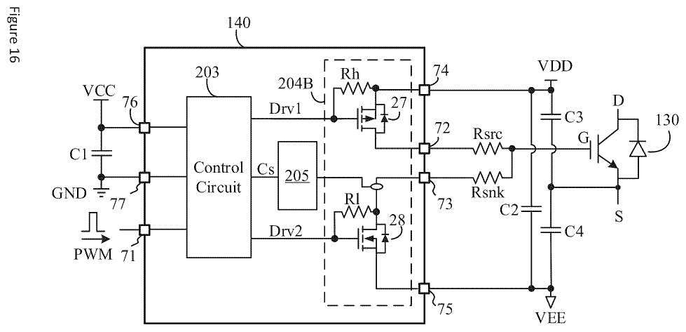

FIG. 15 is a schematic circuit diagram of a switching converter 900 according to an embodiment of the present invention. In the embodiment shown in FIG. 15, the switching converter 900 may include the power switching devices 801 to 802 and a driver 901. The driver 901 may be integrated on an integrated circuit, for example. The driver 901 may include an input pin 91, an output pin 92, a reference ground pin 93, a power supply pin 94, an input pin 95, an output pin 96, a reference ground pin 97, a power supply pin 98, a power supply pin 31, a reference ground pin 32, control circuits 902 to 903, driving circuits 904 to 905, and current sensing circuits 906 to 907.

The input pin 91 may receive the switching control signal PWM1, the output pin 92 may be coupled to the control terminal G of the power switching device 801 through the resistor Rg1 and may provide the driving voltage Vg1 to control the turn-on and turn-off switching of the power switching device 801, the reference ground pin 93 may be coupled to the power terminal S of the power switching device 801, and the power supply pin 94 may receive the power supply voltage VDD. The input pin 95 may receive the switching control signal PWM2, the output pin 96 may be coupled to the control terminal G of the power switching device 802 through the resistor Rg2 and may provide the driving voltage Vg2 to control the turn-on and turn-off switching of the power switching device 802, the reference ground pin 97 may be coupled to the power terminal S of the power switching device 802, and the power supply pin 98 may receive a power supply voltage VDD2. In one embodiment, the supply voltage VDD2 may be equal to the supply voltage VDD. The power supply pin 31 may receive the power supply voltage VCC, the reference ground pin 32 may be coupled to the reference ground GND, and a capacitor C13 may be coupled between the power supply pin 31 and the reference ground pin 32.

The control circuit 902 may be coupled to the power supply pin 31 and the reference ground pin 32, and the power supply voltage VCC may supply power to the control circuit 902. The control circuit 902 may generate a driving control signal Drv1 according to the switching control signal PWM1 and the current Ig1 flowing through the control terminal G of the power switching device 801. In one embodiment, the switching control signal PWM1 and the driving control signal Drv1 may be electrically isolated from each other. A power supply terminal of the driving circuit 904 may be coupled to the power supply pin 94, a reference ground terminal of the driving circuit 904 may be coupled to the reference ground pin 93, an input terminal of the driving circuit 904 may be coupled to the control circuit 902 to receive the driving control signal Drv1, and an output terminal of the driving circuit 904 may be coupled to the output pin 92 to provide the driving voltage Vg1.

The control circuit 903 may be coupled to the power supply pin 31 and the reference ground pin 32, and the power supply voltage VCC may supply power to the control circuit 903. The control circuit 903 may generate a driving control signal Drv2 according to the switching control signal PWM2 and the current Ig2 flowing through the control terminal G of the power switching device 802. In one embodiment, the switching control signal PWM2 and the driving control signal Drv2 may be electrically isolated from each other. A power supply terminal of the driving circuit 905 may be coupled to the power supply pin 98, a reference ground terminal of the driving circuit 905 may be coupled to the reference ground pin 97, an input terminal of the driving circuit 905 may be coupled to the control circuit 903 to receive the driving control signal Drv2, and an output terminal of the driving circuit 905 may be coupled to the output pin 96 to provide the driving voltage Vg2. In another embodiment, the control circuit 903 may also generate the driving control signal Drv2 according to the switching control signal PWM1 and the current Ig2 flowing through the control terminal G of the power switching device 802, and the switching control signal PWM1 and the driving control signal Drv2 may be electrically isolated from each other.

FIG. 16 is a schematic circuit diagram of a driver 140 for driving a power switching device 130 according to an embodiment of the present invention. The driver 140 may be integrated on an integrated circuit, for example. In the embodiment shown in FIG. 16, the driver 140 may include an input pin 71, an output pin 72, an output pin 73, a power supply pin 74, a reference ground pin 75, a power supply pin 76, a reference ground pin 77, the control circuit 203, a driving circuit 204B and the current sensing circuit 205. The input pin 71 may receive the switching control signal PWM, the output pin 72 may be coupled to a control terminal G of the power switching device 130 through a resistor Rsrc, the output pin 73 may be coupled to the control terminal G of the power switching device 130 through a resistor Rsnk, the power supply pin 74 may be coupled to the power supply voltage VDD, the reference ground pin 75 may be coupled to the reference ground VEE, the power supply pin 76 may be coupled to the power supply voltage VCC, and the reference ground pin 77 may be coupled to the reference ground GND. In one embodiment, a capacitor C2 may be coupled between the power supply pin 74 and the reference ground pin 75, a capacitor C3 may be coupled between the power supply pin 74 and a power terminal S of the power switching device 130, and a capacitor C4 may be coupled between the power terminal S of the power switching device 130 and the reference ground pin 75. In one embodiment, a capacitor C1 may be coupled between the power supply pin 76 and the reference ground pin 77. In one embodiment, the control circuit 203 may be coupled to the power supply pin 76 and the reference ground pin 77, and the power supply voltage VCC may supply power to the control circuit 203. In one embodiment, the switching control signal PWM and the driving control signal (for example, shown as a driving control signal Drv1 and a driving control signal Dr2 in FIG. 16) may be electrically isolated from each other. The control circuit 203 may generate the driving control signal (for example, the driving control signal Drv1 and the driving control signal Drv2) according to the switching control signal PWM and the current flowing through the control terminal G of the power switching device 130. The driving circuit 204B may be coupled between the power supply pin 74 and the reference ground pin 75 and may control the turn-on and turn-off switching of the power switching device 130 through the output pin 72 and the output pin 73 under the control of the driving control signal (for example, the driving control signal Drv1 and the driving control signal Drv2). For example, the driving circuit 204B may turn on the power switching device 130 through the output pin 72 and turn off the power switching device 130 through the output pin 73. In one embodiment, when the switching control signal PWM is at the first state, the driver 140 may control the power switching device 130 to be turned on according to the current flowing through the control terminal G of the power switching device 130, and when the switching control signal PWM is at the second state, the driver 140 may control the power switching device 130 to be turned off.

In the embodiment shown in FIG. 16, the driving circuit 204B may include switches 27 to 28. A first terminal of the switch 27 may be coupled to the power supply pin 74, a second terminal of the switch 27 may be coupled to the output pin 72, and a control terminal of the switch 27 may be coupled to the control circuit 203 and the switch 27 may be turned on and off under the control of the driving control signal Drv1. A first terminal of the switch 28 may be coupled to the output pin 73, a second terminal of the switch 28 may be coupled to the reference ground pin 75, and a control terminal of the switch 28 may be coupled to the control circuit 203 and the switch 28 may be turned on and off under the control of the driving control signal Drv2. In one embodiment, a resistor Rh may be coupled between the power supply pin 74 and the control terminal of the switch 27, and a resistor Rl may be coupled between the output pin 73 and the control terminal of the switch 28. When the power supply voltage VDD is small, the switch 27 may remain off, and the control terminal of the switch 28 may connected to the output pin 73 through the resistor RI. In one embodiment, the current sensing circuit 205 may sense a current flowing through the switch 28 to generate the current sensing signal Cs. When the switching control signal PWM is at the first state, the driver 140 may control the power switching device 130 to be turned on according to a comparison result of the current sensing signal Cs and the current threshold Iref. In one embodiment, the control circuit 203 may generate the driving control signal Drv1 and the driving control signal Drv2 according to the switching control signal PWM and the current flowing through the control terminal G of the power switching device 130.

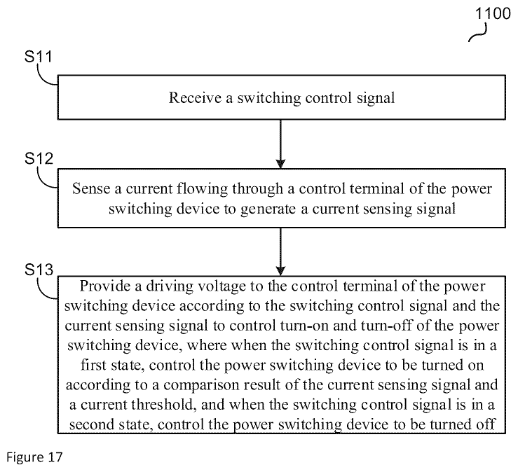

FIG. 17 is a flowchart of a driving method 1100 of a power switching device according to an embodiment of the present invention. The method 1100 may include steps S11 to S13.

Step S11, receiving a switching control signal. Step S12, sensing a current flowing through a control terminal of the power switching device to generate a current sensing signal. Step S13, providing a driving voltage to the control terminal of the power switching device according to the switching control signal and the current sensing signal to control turn-on and turn-off switching of the power switching device, where when the switching control signal is at a first state, controlling the power switching device to be turned on according to a comparison result of the current sensing signal and a current threshold, and when the switching control signal is at a second state, controlling the power switching device to be turned off.

In one embodiment, controlling the power switching device to be turned on according to the comparison result of the current sensing signal and the current threshold when the switching control signal is at the first state may include: adjusting, according to the comparison result of the current sensing signal and the current threshold, a delay time between a moment when the switching control signal changes to the first state and a moment when the driving voltage starts to change to turn on the power switching device. When the delay time reaches a preset duration, the power switching device is controlled to be turned on.

It should be noted that the execution sequence of each step in the above flowchart is not limited to that shown in FIG. 17, and two consecutive function blocks can be executed simultaneously or in reverse order, for example, step S12 can be executed simultaneously with step S11 or before step S11.

Although the present invention has been described with reference to several exemplary embodiments, it should be understood that the terminology used herein is illustrative and exemplary rather than limiting. As the present invention can be embodied in various forms without departing from the spirit or essence of the present invention, it should be understood that the above-mentioned embodiments are not limited to any of the foregoing details, but should be broadly interpreted within the spirit and scope defined by the appended claims, and therefore all changes and modifications that fall within the scope of the claims or their equivalents are intended to be covered by the appended claims.

What is claimed is:

1. A driver for a power switching device, comprising:
an input terminal, configured to receive a switching control signal; and
an output terminal, coupled to a control terminal of the power switching device, and configured to provide a driving voltage to control turn-on and turn-off switching of the power switching device;
wherein when the switching control signal is at a first state, the driver is configured to control the power switching device to be turned on according to a current flowing through the control terminal of the power switching device, and when the switching control signal is at a second state, the driver is configured to control the power switching device to be turned off.

2. The driver of claim 1, further comprising:
a power supply terminal, configured to receive a power supply voltage;
a control circuit, configured to generate a driving control signal according to the switching control signal and the current flowing through the control terminal of the power switching device; and
a driving circuit, coupled between the power supply terminal and a power terminal of the power switching device, and configured to generate the driving voltage under the control of the driving control signal.

3. The driver of claim 1, wherein the driver is further configured to adjust, according to the current flowing through the control terminal of the power switching device, a delay time between a moment when the switching control signal changes to the first state and a moment when the driving voltage starts to change to turn on the power switching device.

4. The driver of claim 3, wherein the control circuit is further configured to control the power switching device to be turned on when the delay time reaches a preset duration.

5. The driver of claim 1, further comprising:
a current sensing circuit, configured to sense the current flowing through the control terminal of the power switching device to generate a current sensing signal; wherein
when the switching control signal is at the first state, the driver is configured to control the power switching device to be turned on according to a comparison result of the current sensing signal and a current threshold.

6. The driver of claim 2, wherein the driving circuit comprises:
a first switch, comprising a first terminal, a second terminal and a control terminal, wherein the first terminal of the first switch is coupled to the power supply voltage, and the control terminal of the first switch is coupled to the control circuit; and
a second switch, comprising a first terminal, a second terminal and a control terminal, wherein the second terminal of the second switch is coupled to one of the power terminals of the power switching device, and the control terminal of the second switch is coupled to the control circuit, and wherein
the second terminal of the first switch and the first terminal of the second switch jointly provide the driving voltage.

7. The driver of claim 2, further comprising:
a current sensing circuit, configured to sense the current flowing through the control terminal of the power switching device to generate a current sensing signal; wherein the control circuit further comprises:
a zero-voltage turn-on control circuit, configured to provide a zero-voltage turn-on control signal according to a comparison result of the current sensing signal and a current threshold; and
a logic circuit, configured to generate the driving control signal according to the switching control signal and the zero-voltage turn-on control signal.

8. The driver of claim 7, wherein the control circuit further comprises:
a signal processing circuit, configured to provide a turn-on control signal and a turn-off control signal according to the switching control signal.

9. The driver of claim 8, wherein the signal processing circuit comprises:
a first isolating capacitor, configured to electrically isolate the turn-on control signal from the switching control signal; and
a second isolating capacitor, configured to electrically isolate the turn-off control signal from the switching control signal.

10. A driver for a power switching device, comprising:
an input pin, configured to receive a switching control signal;
a first output pin, coupled to a control terminal of the power switching device through a first resistor;
a second output pin, coupled to the control terminal of the power switching device through a second resistor;
a power supply pin, configured to receive a power supply voltage;
a reference ground pin;
a control circuit, configured to generate a driving control signal according to the switching control signal and a current flowing through the control terminal of the power switching device; and
a driving circuit, coupled between the power supply pin and the reference ground pin, and configured to control turn-on and turn-off switching of the power switching device through the first output pin and the second output pin under the control of the driving control signal.

11. The driver of claim 10, wherein the driving circuit comprises:
a first switch, comprising a first terminal, a second terminal and a control terminal, wherein the first terminal of the first switch is coupled to the power supply pin, the second terminal of the first switch is coupled to the first output pin, and the control terminal of the first switch is coupled to the control circuit; and
a second switch, comprising a first terminal, a second terminal and a control terminal, wherein the first terminal of the second switch is coupled to the second output pin, the second terminal of the second switch is coupled to the reference ground pin, and the control terminal of the second switch is coupled to the control circuit.

12. The driver of claim 11, further comprising:
a current sensing circuit, configured to sense a current flowing through the second switch to generate a current sensing signal; wherein
when the switching control signal is at a first state, the driver is configured to control the power switching device to be turned on according to a comparison result of the current sensing signal and a current threshold.

13. The driver of claim 11, further comprising:
a third resistor, coupled between the power supply pin and the control terminal of the first switch; and
a fourth resistor, coupled between the second output pin and the control terminal of the second switch.

14. A driver for driving a first power switching device, comprising:
a first input pin, configured to receive a first switching control signal;
a first output pin, coupled to a control terminal of the first power switching device, and configured to provide a first driving voltage to the control terminal of the first power switching device;
a first power supply pin, configured to receive a first power supply voltage;
a first reference ground pin;
a second power supply pin, configured to receive a second power supply voltage;
a second reference ground pin;
a first control circuit, coupled to the first reference ground pin and the first power supply pin to receive the first power supply voltage, and configured to generate a first driving control signal according to the first switching control signal and a current flowing through the control terminal of the first power switching device; and
a first driving circuit, coupled between the second power supply pin and the second reference ground pin, and configured to generate the first driving voltage under the control of the first driving control signal.

15. The driver of claim 14, wherein the first driving control signal and the first switching control signal are electrically isolated by an isolating capacitor.

16. The driver of claim 14, wherein the first control circuit comprises:
a signal processing circuit, configured to provide a turn-on control signal and a turn-off control signal according to the first switching control signal, wherein the signal processing circuit comprises a first isolating capacitor which electrically isolates the turn-on control signal from the first switching control signal, and a second isolating capacitor which electrically isolates the turn-off control signal from the first switching control signal.

17. The driver of claim 16, further comprising:
a current sensing circuit, configured to sense the current flowing through the control terminal of the first power switching device to generate a current sensing signal;
wherein the first control circuit further comprises:
a zero-voltage turn-on control circuit, configured to provide a zero-voltage turn-on control signal according to a comparison result of the current sensing signal and a current threshold; and
a logic circuit, configured to generate the first driving control signal according to the turn-on control signal, the turn-off control signal, and the zero-voltage turn-on control signal.

18. The driver of claim 14, further configured to drive a second power switching device, and further comprising:
a second input pin, configured to receive a second switching control signal;
a second output pin, coupled to a control terminal of the second power switching device and configured to provide a second driving voltage to the control terminal of the second power switching device.

19. The driver of claim 18, further comprising:
a third power supply pin, configured to receive a third power supply voltage;
a third reference ground pin, coupled to a power terminal of the second power switching device;
a second control circuit, coupled to the first reference ground pin and the first power supply pin to receive the first power supply voltage, and configured to generate a second driving control signal according to the second switching control signal and a current flowing through the control terminal of the second power switching device; and
a second driving circuit, coupled between the third power supply pin and the third reference ground pin, and configured to generate the second driving voltage under the control of the second driving control signal.

20. A voltage converter, comprising:
a power switching device and a driver, wherein the driver comprises:
an input terminal, configured to receive a switching control signal;
an output terminal, coupled to a control terminal of the power switching device, and configured to provide a driving voltage to control turn-on and turn-off switching of the power switching device; wherein
when the switching control signal is at a first state, the driver is configured to control the power switching device to be turned on according to a current flowing through the control terminal of the power switching device, and when the switching control signal is at a second state, the driver is configured to control the power switching device to be turned off.
